(19) United States
(12) Patent Application Publication
(10) Pub. No.: US 2005/0112843 A1
(43) Pub. Date: May 26, 2005

(54) Method for anodic bonding of wafers and device

(76) Inventors: Frank Fischer, Gomaringen (DE); Eckhard Graf, Gomaringen (DE)

Correspondence Address: KENYON & KENYON, ONE BROADWAY, NEW YORK, NY, 10004, US

(21) Appl. No.: 10/956,997

(22) Filed: Sep. 30, 2004

(30) Foreign Application Priority Data
Oct. 27, 2003 (DE) 10350038.3

(51) Int. Cl. H01L 21/00; H01L 27/01; H01L 27/12; H01L 31/0392; H01L 21/30

(52) U.S. Cl. 438/455; 257/347

(57) ABSTRACT

A method for anodic bonding of wafers and a device essentially composed of such bonded wafers. An intermediate layer is placed between two wafers, after which the two wafers are anodically bonded. The method and the device have the advantage of being implementable and manufacturable, respectively, in a particularly cost-effective manner. The anodically bonded intermediate layer plastically encloses any possible particles present or evens out differences in height of the wafer surfaces to be bonded and thus prevents any extensive bond defects from occurring.

### BACKGROUND INFORMATION

Manufacturing of SOI (silicon on insulator) wafers was originally motivated by the development of microelectronics to achieve better electrical insulating of the integrated circuit against the substrate, for example for high-current or high-temperature applications. A typical SOI wafer which is suitable for processing microelectronic circuits has a base wafer which has a typical thickness between 800 μm and 300 μm. A thin oxide, which has a thickness of approximately 0.5 μm to 2 μm, is applied to the base wafer. A monocrystalline silicon layer having a thickness between 1 μm and 100 μm is situated over the oxide. The crystal quality of the upper silicon layer is important for implementing the integrated circuit elements.

In the past few years, SOI wafers have increasingly aroused the interest of manufacturers of microelectromechanical structures (MEMS). In particular, for applications in the area of optical MEMS components or rotational speed sensors, demos and new functions are being increasingly shown. Advantages compared to thin-film technologies, with the exception of polysilicon epitaxy, include the absence of a stress gradient, and the possibility of producing thick layers and planar surfaces.

Two approaches have been used for manufacturing such wafer substrates.

In the first approach, known as the SIMOX method, very high doses of oxygen are implanted in a monocrystalline silicon wafer. In the subsequent healing of the radiation damage at very high temperatures, a buried oxide layer having a thickness of approximately 0.5 μm is formed. A thin silicon layer is recrystallized over the oxide layer and forms an undisturbed monocrystalline film. Subsequently a thicker monocrystalline layer is grown on this silicon nucleus layer using an epitaxial method. The IC components are formed later in this epitaxially grown layer. The SIMOX method is very expensive because it needs equipment for high-current oxygen implantation. In addition, in this method the thickness of the useful silicon layer and of the oxide layer is limited. Another constructive limitation of the SIMOX method is that it is not possible to run buried printed conductors underneath the functional layer. The printed conductors must be run on the surface. Encapsulation of the micromechanical components is thus made considerably more difficult because it is then impossible to provide a topography-free bond frame for the cap in a simple manner.

In the second approach, the base wafer is provided with a thin layer of thermal oxide. A second wafer is bonded onto this oxide layer using a direct bonding method. This wafer is thinned from the back side to the desired target thickness, damage etched, and polished. The problem in any direct bonding method is the yield and therefore the cost. Direct bonding methods are highly sensitive to particles which result in extensive bond occlusions. Therefore, significant yield losses are to be expected when the oxide layer is structured. In the direct bonding method it is not possible to run buried printed conductors underneath the functional layer, because extensive bond defects may occur due to the topography. This in turn makes encapsulation difficult.

### SUMMARY OF THE INVENTION

The present invention is directed to a method for anodically bonding wafers and to a device.

An essence of the present invention is that an intermediate layer is placed between two wafers, after which the two wafers are anodically bonded.

The method and the device according to the present invention have the advantage of being implementable and manufacturable, respectively, in a particularly cost-effective manner. The anodically bonded intermediate layer plastically encloses any possible particles present or evens out differences in height of the wafer surfaces to be bonded and thus prevents any extensive bond defects from occurring.

The manufacture of SOI wafers using the method according to the present invention is particularly advantageous.

In an advantageous embodiment of the method, the intermediate layer is a glass layer, and it is applied by spin-on deposition to at least one of the two wafers. The intermediate layer may be distributed evenly on the wafer and it may produce an even surface.

The bondable intermediate layer is structured in a further advantageous embodiment of the present invention. Structuring may be performed, for example, if a cavity is formed between the base wafer and the second wafer when bonding. This cavity may be involved in the manufacturing of freely movable sensor structures.

It is furthermore advantageous that the intermediate layer is formed such that it plastically encloses any particles present and evens out height differences of the bonded surfaces. This ensures that no extensive bond defects occur during bonding.

It is particularly advantageous that second wafer (1, 100, 200, 300) may have several layers, in particular a silicon substrate (1) and further layers (3, 4, 403). If these layers are structured in some way, the intermediate layer is able to even out any height differences of the surfaces caused by structuring and thus prevent bond defects.

In another particularly advantageous embodiment of the present invention, an electrically insulated conductive layer is produced on the silicon functional layer of the second wafer. This conductive layer may be structured to form printed conductors, which are locally bonded to the functional layer. They establish the electrical connection between the electromechanical structures of an MEMS component, which are not defined until the base wafer and the functional layer are joined. By combining several structured conductive and insulating layers, there is a possibility to establish almost any electrical connection within the bond surface, so that even more complex sensor structures, for example, having intersecting printed conductors, may be designed. In addition, buried printed conductors allow flat surfaces to be formed on the top of the functional layer, so that known encapsulating methods such as bonding may be used.

The method allows acceleration sensors or rotational speed sensors, for example, having buried printed conductors to be manufactured in a four-mask process, the functional layer being able to have any desired thickness. In addition, doping of the functional layer, planarization, or protective oxides are not needed.

A device according to the present invention is advantageously manufactured in particular according to the method of the present invention.

### BRIEF DESCRIPTION OF THE DRAWINGS

FIGS. 1A through 1E show the anodic bonding of a base wafer with an intermediate layer and a second wafer using the illustrated process steps.

FIG. 1A shows a silicon substrate having a deposited intermediate layer.

FIG. 1B shows the structuring of the intermediate layer.

FIG. 1C shows the anodic bonding of the second wafer onto the intermediate layer.

FIG. 1D shows the thinning of the substrate from the back.

FIG. 1E shows the application of a contact metal and structuring of a functional layer.

FIGS. 2A through 2E show the anodic bonding of a base wafer with an intermediate layer and a second wafer having a substrate and two further insulating layers, using the illustrated process steps.

FIG. 2A shows a substrate having an insulating sacrificial layer, a further insulating layer, and an intermediate layer.

FIG. 2B shows the anodic bonding of the base wafer with the intermediate layer and the second wafer.

FIG. 2C shows the thinning of the substrate from the back.

FIG. 2D shows the application and structuring of a contact metal and structuring of a functional layer.

FIG. 2E shows the etching of the sacrificial layer.

FIGS. 3A through 3C show the anodic bonding of a base wafer with an intermediate layer and a second wafer having a substrate, a structured insulating layer, and a further insulating layer, using the illustrated process steps.

FIG. 3A shows a base wafer having an intermediate layer, a structured insulating layer, and the additional insulating layer.

FIG. 3B shows the bonding of the two wafers and the structuring of the second wafer.

FIG. 3C shows the etching of the sacrificial layer.

FIGS. 4A through 4F show the anodic bonding of a base wafer with an intermediate layer and a second wafer having a substrate, a structured insulating layer, and buried conductor structures, using the illustrated process steps.

FIG. 4A shows an insulating layer and the conductive layer being applied to the substrate.

FIG. 4B shows the evening out of the topography via coating.

FIG. 4C shows the anodic bonding of the base wafer.

FIG. 4D shows the thinning of the substrate from the back.

FIG. 4E shows the application of the contact metal and structuring of the functional layer.

FIG. 4F shows the etching of the sacrificial layer.

FIG. 5 shows a device according to the present invention having a cap wafer bonded thereto.

### DETAILED DESCRIPTION

The present invention is described in detail with reference to the following exemplary embodiments.

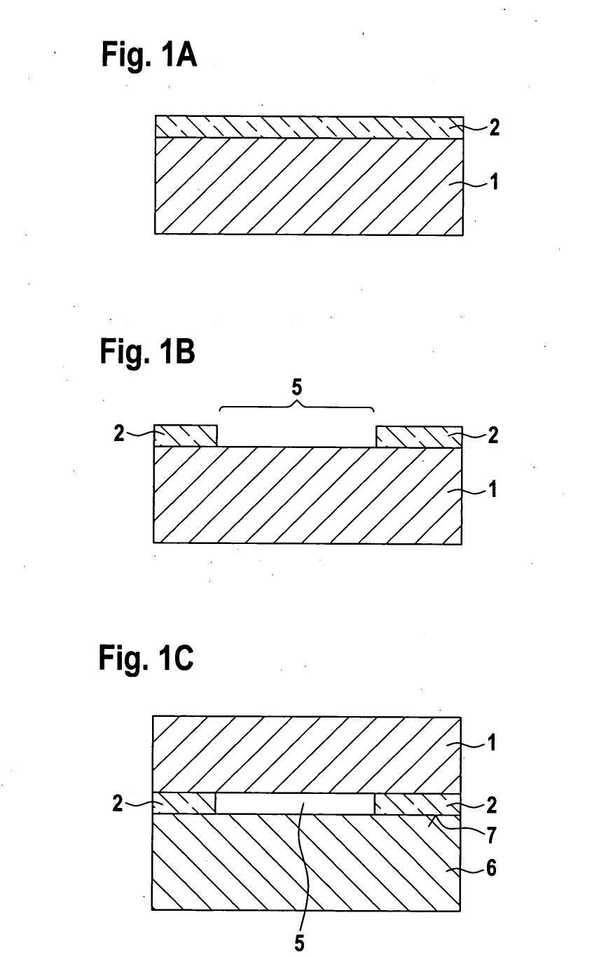

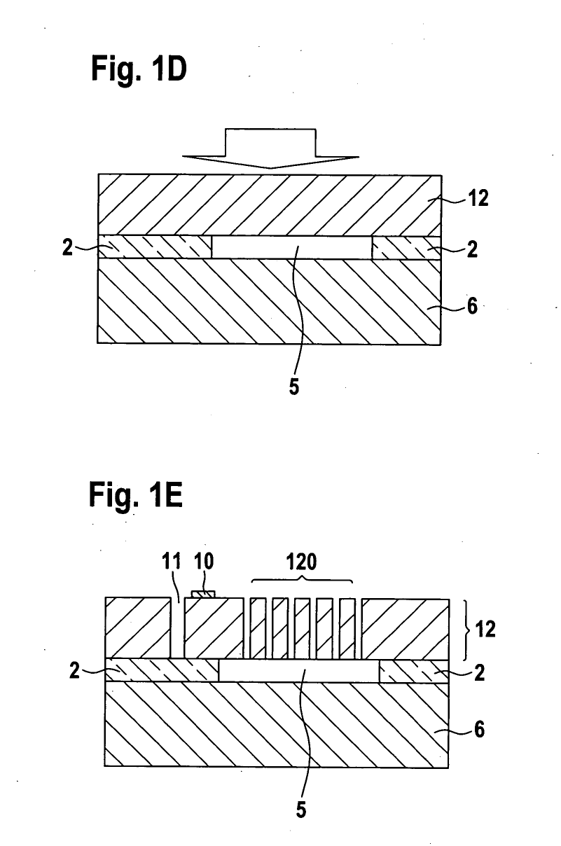

FIGS. 1A through 1E show the anodic bonding of a base wafer with an intermediate layer and a second wafer. In one embodiment of the method, an SOI wafer is manufactured in this way. FIG. 1A shows a silicon substrate 1 and deposited intermediate layer 2. In an advantageous embodiment of the method according to the present invention, a glass layer 2 is applied as intermediate layer 2 to silicon substrate 1, using a spin-on-glass technique (SOG), and heated, so that a planar surface is obtained on layer 2. As shown in FIG. 1B, layer 2 may be structured by etching, for example, so that recesses 5, which are subsequently located underneath the sensor structure, are obtained. The etching step creates adjustment marks for recesses 5, which may be used for the subsequent adjustment of the back surfaces. Layer 2 may, however, also be processed unstructured. In the following step, as shown in FIG. 1C, substrate 1, which here represents second wafer 1, is bonded onto SOG layer 2 of base wafer 6. According to the present invention, anodic bonding is used for this procedure. Particles on bond surface 7 have a much less significant role here than in direct bonding methods, for example. FIG. 1D illustrates the subsequent thinning of substrate 1. Substrate 1 is thinned from the back, etched, and polished. Functional layer 12 is obtained in this way. The final thickness of monocrystalline layer 12 should be approximately 10 μm to 200 μm. No subsequent doping is needed. FIG. 1E shows the application of contact metal 10 (preferably Al(SiCu)) and structuring of functional layer 12. Contact metal 10 is applied and structured first. A structured masking layer (not shown) is then applied, which defines the mechanical components of the component structure for the subsequent deep etching step. To structure insulating trenches 11 and movable structures 120 in functional layer 12, a deep etching method, known from the related art, is preferably used. At this point, the method for manufacturing a microelectromechanical structure is complete even without sacrificial layer etching, because recess 5 is directly underneath movable sensor structure 120. In the case of bonding according to FIG. 1C using an unstructured SOG layer, this layer would still have to be etched.

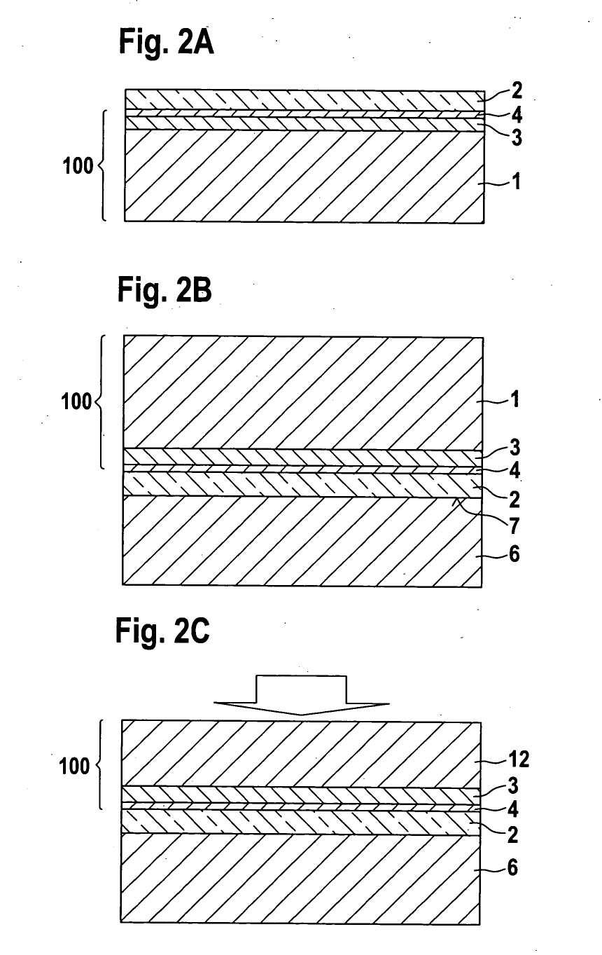

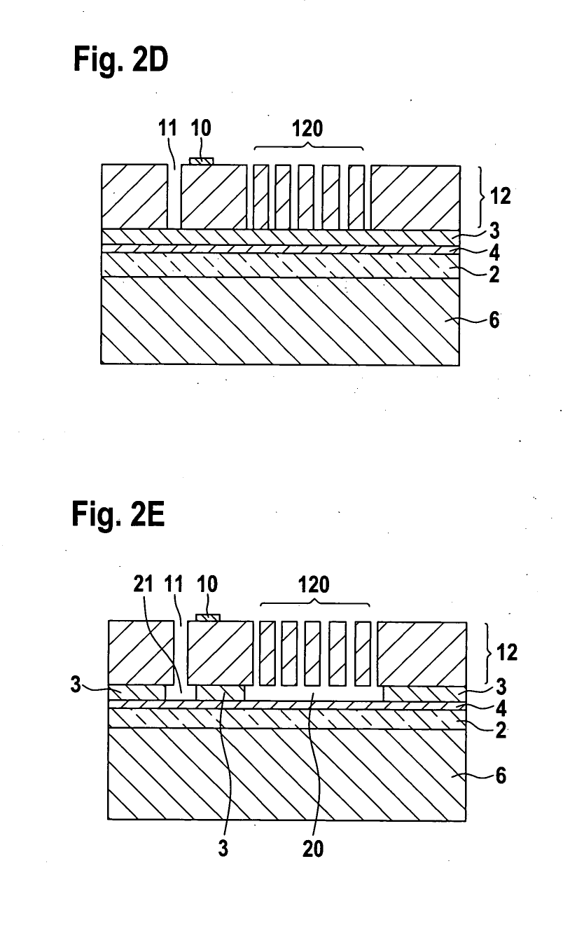

FIGS. 2A through 2E show another embodiment of the method according to the present invention, the anodic bonding of a base wafer with an intermediate layer and a second wafer having a substrate and two further insulating layers. In one embodiment of the method, an SOI wafer is manufactured in this way. FIG. 2A shows how an additional unstructured intermediate layer 3 (e.g., oxide), which may later be removed using a known sacrificial layer etching process, is produced on substrate 1. Subsequently next insulating layer 4, which is not attacked later during sacrificial layer etching, is produced on this layer. SiN may be applied, for example. Finally, an anodically bondable intermediate layer 2 is applied thereon, which, in one embodiment of the method, may be an SOG layer. Substrate 1 having layers 3 and 4 forms second wafer 100. As shown in FIG. 2B, second wafer 100 having surface 7 of SOG layer 2 is anodically bonded onto base wafer 6. FIG. 2C illustrates how substrate 1 is thinned from the back to a targeted thickness, etched, and polished. Functional layer 12 is obtained in this way. No subsequent doping is needed. FIG. 2D shows the application and structuring of contact metal 10 and structuring of functional layer 12. Contact metal 10 (preferably Al(SiCu)) is applied and structured in this process. A structured masking layer (not shown) is then applied. The masking layer defines the mechanical components of the component structure for the subsequent deep etching step. To structure functional layer 12 into movable structures 120 and insulating trenches 11, a deep etching method, known from the related art, is preferably used. Additional wafer 100 includes functional layer 12, sacrificial layer 3, and etching-resistant insulating layer 4. A sacrificial layer etching process, which selectively removes layer 3 with respect to layers 4 and 12 in region 20 underneath movable structures 12 of functional layer 12 and in region 21 underneath insulating trench 11, is then performed according to FIG. 2E. The process of manufacturing a microelectromechanical structure is thus completed.

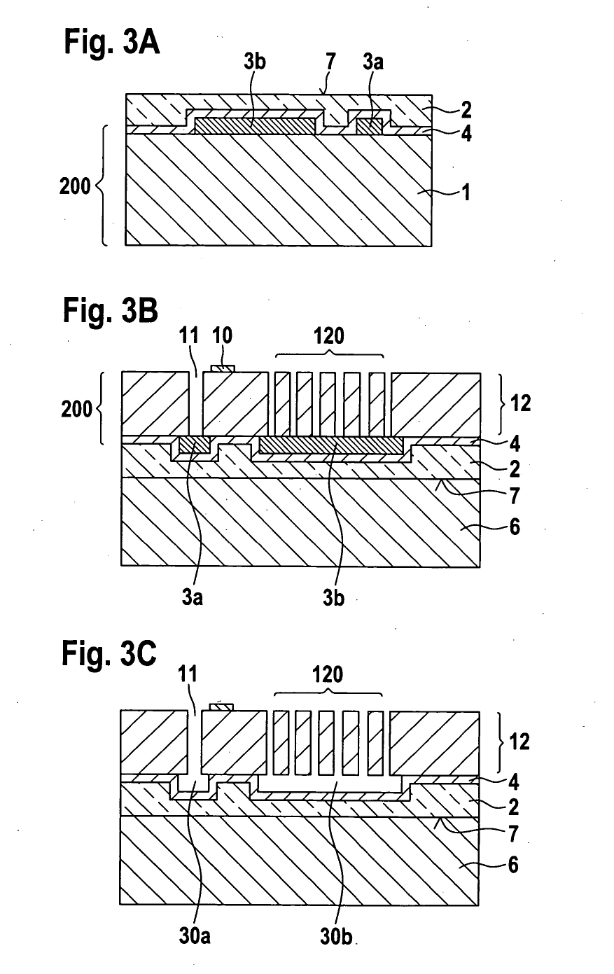

In another embodiment of the method according to the present invention, FIGS. 3A through 3C show the anodic bonding of a base wafer with an intermediate layer and a second wafer having a substrate, a structured insulating layer, and a further insulating layer. In particular, an SOI wafer may be manufactured in this way. FIG. 3A shows substrate 1, on which insulating layer 3 is produced. Insulating layer 3 is structured in regions 3a, 3b and represents a sacrificial layer. An additional insulating layer 4 is deposited thereon, which is preferably resistant to sacrificial layer etching. Layers 1, 3a, 3b, and 4 together form second wafer 200. Intermediate layer 2 is applied onto layer 4 in such a way that a surface 7 is obtained. Intermediate layer 2 may be SOG layer 2 in particular. FIG. 3B shows a bonded SOI wafer having a structured functional layer. For this purpose, second wafer 200 having surface 7 of SOG layer 2 is first bonded onto base wafer 6. Subsequently, substrate 1 is thinned from the back and structured in such a way that functional layer 12 having insulating trenches 11 and movable structures 120 is obtained. When functional layer 12 is deep structured, insulating trenches 11 and movable structures 120 are defined over regions 3a and 3b in the sacrificial layer, which laterally border, on all sides, on regions of layer 4. FIG. 3C shows etching of sacrificial layer 3. During the final sacrificial layer etching, parts of sacrificial layer 3a underneath insulating trenches 11 and parts of sacrificial layer 3b under movable structures 120 of functional layer 12 are removed. The etching operation selectively stops at the surface of insulating layer 4 (e.g., SiN), so that no undesirable underetching of functional layer 12 occurs. The etching process produces cavities 30a underneath insulating trenches 11 and cavities 30b underneath movable structures 120. The insulating trenches extend together with cavity 30b up to insulating layer 4. Structures 120 become movable due to the formation of cavities 30b.

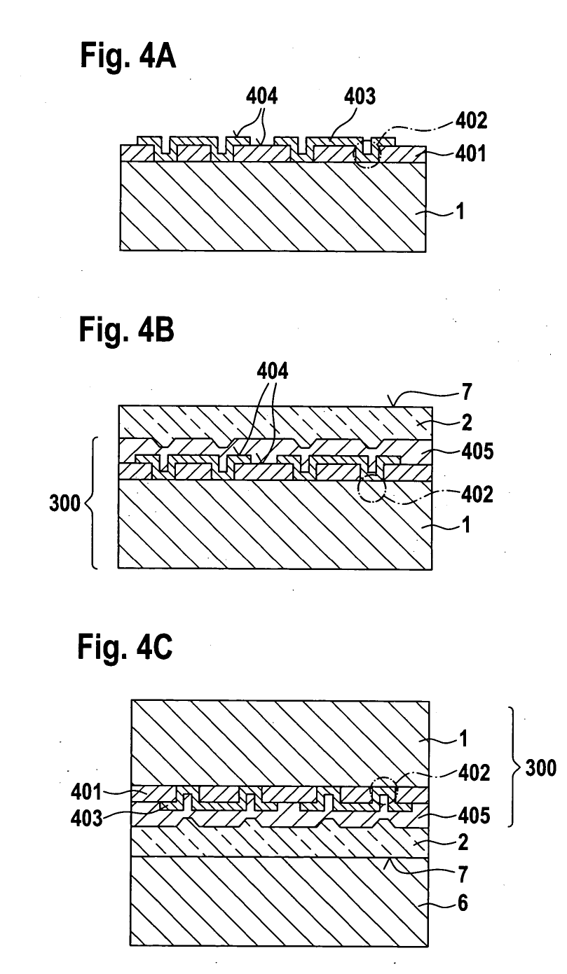

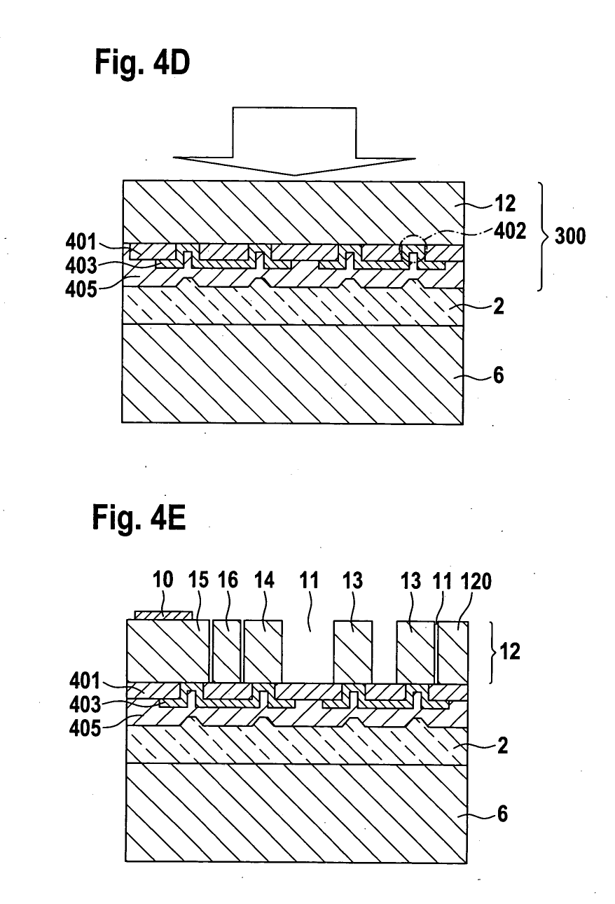

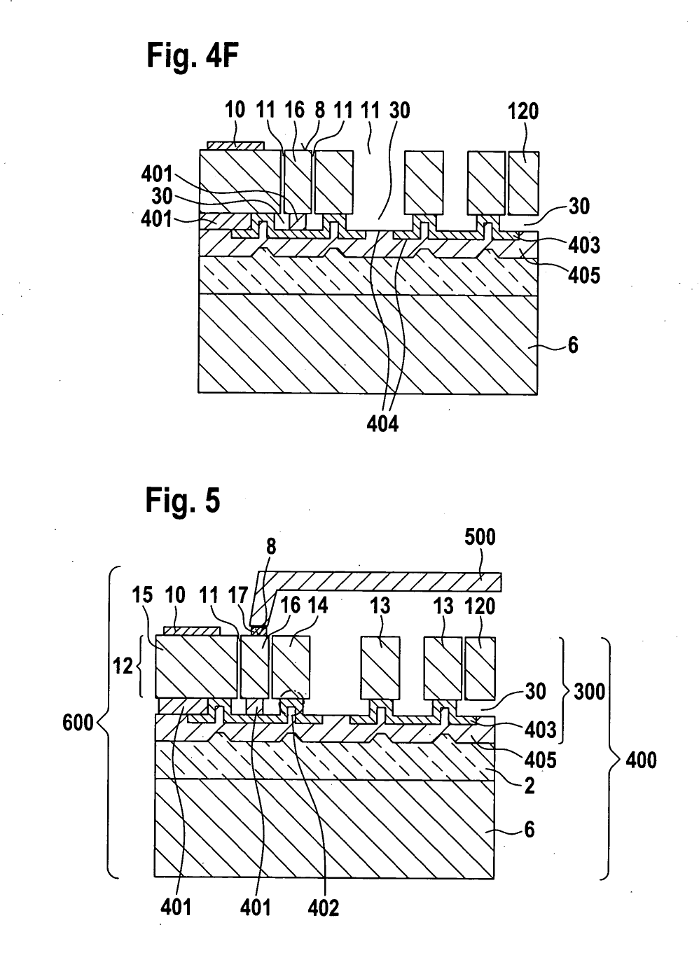

FIGS. 4A through 4F show the anodic bonding of a base wafer with an intermediate layer, a structured insulating layer, and buried conductor structures. FIG. 4A shows the application of an insulating layer and a conductive layer onto a substrate. A first insulating layer 401 is first produced on an Si substrate 1, which is preferably doped so it becomes conductive. This is performed, for example, using thermal oxidation, TEOS, PECVD oxide, or similar methods. Subsequently, insulating layer 401 is structured in such a way that contact orifices 402 pointing toward substrate 1 underneath are obtained. Structuring is performed, for example, by wet or dry structuring or local oxidation of silicon (LOCOS). First insulating layer 401 is then provided with a conductive layer 403, which is preferably made of polycrystalline silicon or silicide, etc. Parts of conductive layer 403 are structured to form printed conductors 403. Optionally, according to the present invention, printed conductor structuring may be followed by deposition of a second insulating layer, which is not illustrated here. The optional second insulating layer covers all surfaces 404 on conductive layer 403 and first oxide 401. This layer is unstructured and may have a thickness of approximately 50 nm to 0.5 μm. According to the present invention, the second insulating layer is made of a material, for example SiN, which is not attacked by the reaction gases in a later sacrificial etching process.

According to FIG. 4B, in the following step the structured surface is evened out by coating. One or more layers 405, which are not structured, are applied to printed conductor 403, i.e., to optional second insulating layer and accessible surfaces of layer 401. Layer 405 may be an insulator or, if the optional second insulating layer is used, a conductive material. Preferably a material is used which fully or partially evens out any height differences of surface 404, in particular over contact orifices 402. Methods such as TEOS, TEOS:O3, spin on glass, or the like may be used for coating. Another possibility is to deposit polycrystalline silicon as layer 405 and to planarize it by chemical or mechanical polishing. Layers 1, 401, 403, and the optional second insulating layer together form second wafer 300. A spin on glass (SOG) coating is applied to layer 405 and subjected to heat treatment. This SOG forms a smooth film having surface 7. According to the present invention, surface 2 may be an alkali-containing SOG.

As shown in FIG. 4C, in the next step second wafer 300 having surface 7 of SOG layer 2 is anodically bonded to base wafer 6. Bond surface 7 is much less sensitive to particle contamination than with direct bonding methods.

FIG. 4D illustrates the subsequent thinning of substrate 1 from the back. Substrate 1 is thinned to a thickness between 10 μm and 100 μm. Functional layer 12 is obtained, which electrically contacts printed conductor 403 via contact orifices 402.

FIG. 4E shows the subsequent application and structuring of contact metal 10 and structuring of functional layer 12. Metal contacts 10 are deposited and structured in the following step. The lithographic mask may be adjusted to buried structures, for example in layer 403, which are easily visible in infrared transmission light. An etching mask (lacquer, oxide mask, etc.) is then defined for the subsequent deep structuring process. Trenches 11 are etched in the deep structuring process. These trenches 11 define external contact stamps 15, bond frames 16, internal contact stamps 14, connected structures 13, and movable functional elements 120.

As shown in FIG. 4F the sacrificial layer is subsequently etched. After deep structuring, the sacrificial layer, i.e., the regions of layer 401 exposed by trenches 11, is etched. The etching operation is selective with respect to layer 403, and it may also penetrate layer 405. By using a suitable second insulating layer, which is not attacked by the etching medium, the etching operation stops selectively at boundary surface 404, so that no uncontrolled underetching of printed conductors 403 occurs. The sacrificial layer etching creates freely movable structures 120 over etched regions 30. Etching is performed in such a way that sacrificial layer 401 remains uninterrupted and largely preserved between conductive layer 403 and layer 405 on the one hand, and bond frame 16 and external contact stamp 15 on the other hand. Resulting gap insulating regions 120, 13, 14, and 15 are electrically connected via printed conductors 403. Internal contact stamp 14 runs underneath bond frame 16 and is connected to external contact stamp 15. As a result, no topography is created on bond surface 8 of bond frame 16.

FIG. 5 shows an embodiment of a device 600 according to the present invention, which has an SOI wafer 400 and a cap wafer 500. Cap wafer 500 is bonded to a bond surface 8 of SOI wafer 400 via a joining medium 17, for example, by seal glass bonding. SOI wafer 400 has first wafer or base wafer 6, intermediate layer 2, and second wafer 300. First wafer 6 and second wafer 300 are anodically bonded via intermediate layer 2. Second wafer 300 includes evening-out layer 405, electrically conductive layer 403, insulating layer or sacrificial layer 401, and functional layer 12. Functional layer 12 is subdivided into external contact stamp 15, bond frame 16, internal contact stamp 14, connected structures 13, and movable functional elements 120 by trenches 11. Regions 120 and 13, as well as 14 and 15, which are insulated from one another by trenches 11, are electrically connected via printed conductors 403. Conductor 403 originating from internal contact stamp 14 runs underneath bond frame 16 and is connected to external contact stamp 15. No topography caused by printed conductors 403 exists on bond surface 8 of bond frame 16. Bond surface 8 is therefore even. Sacrificial layer 401 is uninterrupted between conductive layer 403 and layer 405 on the one hand and bond frame 16 and external contact stamp 15 on the other hand. Metal contact 10 is on external contact stamp 15. There are cavities 30 underneath movable functional elements 120.

1. A method for connecting first and second wafers, comprising:
situating an intermediate layer between the first wafer and the second wafer; and
anodically bonding the first and second wafers.

2. The method according to claim 1, wherein the intermediate layer contains alkali.

3. The method according to claim 1, wherein the method is for manufacturing an SOI wafer.

4. The method according to claim 1, wherein the intermediate layer is a glass layer, and further comprising applying the intermediate layer by spin-on deposition to at least one of the first and second wafers.

5. The method according to claim 1, wherein the intermediate layer is structured.

6. The method according to claim 1, further comprising forming at least one cavity, at least partly delimited by the intermediate layer, between the first wafer and the second wafer during bonding, the first wafer being a base wafer.

7. The method according to claim 1, further comprising forming the intermediate layer such that it at least one of (a) plastically encloses any particles present and (b) evens out height differences of bonded surfaces in such a way that no extensive bond defects occur during bonding.

8. The method according to claim 1, wherein the second wafer has a plurality of layers including a silicon substrate and further layers.

9. The method according to claim 8, further comprising producing at least one conductive layer on the silicon substrate, the at least one conductive layer contacting the silicon substrate via contact surfaces and being structured to form printed conductors.

10. A device comprising:
a first wafer;
a second wafer; and
an intermediate layer situated between the first wafer and the second wafer,
wherein the first and second wafers are anodically bonded.

11. The device according to claim 10, wherein the intermediate layer contains alkali.

12. The device according to claim 10, wherein the intermediate layer is structured.

13. The device according to claim 11, further comprising at least one cavity, partly delimited by the alkaline intermediate layer, situated between the first wafer and the second wafer.

14. The device according to claim 10, wherein the second wafer includes a functional layer and at least one conductive layer situated between the functional layer and the intermediate layer, and wherein the conductive layer has contacts to the functional layer.
